(19) United States
(12) Patent Application Publication
(10) Pub. No.: US 2016/0343715 A1
(43) Pub. Date: Nov. 24, 2016

(54) MEMORY DEVICE

(71) Applicant: Inotera Memories, Inc., Taoyuan City (TW)

(72) Inventor: Tieh-Chiang WU, Taoyuan City (TW)

(21) Appl. No.: 14/720,831

(22) Filed: May 24, 2015

(51) Int. Cl. H01L 27/108; H01L 29/06

(52) U.S. Cl. CPC H01L 27/10826; H01L 29/0642

(57) ABSTRACT

A memory device including a substrate, a gate structure, a first active region, a second active region, and a contact. The gate structure is disposed in the substrate. The first active region and the second active region are disposed in the substrate and are respectively disposed at opposite sides of the gate structure. The gate structure, the first active region, and the second active region form a memory cell. The contact is disposed on and attached to the first active region. An interface between the contact and the first active region is saddle-shaped.

### BACKGROUND

1. Field of Invention

The present invention relates to a memory device.

2. Description of Related Art

A Dynamic Random Access Memory (DRAM) is an essential element in many electronic products. To increase component density and improve overall performance of DRAM, continuous efforts are made by industrial manufacturers to reduce the sizes of transistors for the DRAM. However, as the transistor size is reduced, the junction contact resistance thereof is increased. The array write-back performance is therefore degraded due to the high junction contact resistance.

### SUMMARY

An aspect of the present invention is to provide a memory device including a substrate, a gate structure, a first active region, a second active region, and a contact. The gate structure is disposed in the substrate. The first active region and the second active region are disposed in the substrate and are respectively disposed at opposite sides of the gate structure. The gate structure, the first active region, and the second active region form a memory cell. The contact is disposed on and attached to the first active region. An interface between the contact and the first active region is saddle-shaped.

In one or more embodiments, the first active region is disposed between and attached to adjacent two of the gate structures, and the interface is curved upward toward the two gate structures.

In one or more embodiments, the memory device further includes a first isolation structure disposed between and attached to adjacent two of the first active regions. The interface is curved downward toward the first isolation structure.

In one or more embodiments, a top surface of the first isolation structure is lower than the interface, such that the first active regions form a fin-shaped structure.

In one or more embodiments, the memory device further includes a gate dielectric disposed between the gate structure and the first active region and between the gate structure and the second active region.

In one or more embodiments, the memory device further includes an interlayer dielectric disposed on or above the second active region.

In one or more embodiments, the memory cell includes one of the first active region, two of the gate structures, and two of the second active regions. The first active region is disposed between the gate structures, and each of the gate structures is disposed between the first active region and one of the second active regions.

In one or more embodiments, the memory device further includes a plurality of second isolation structures. The memory cell is disposed between adjacent two of the second isolation structures.

In one or more embodiments, the gate structure includes a first portion and a second portion disposed between the first portion and the first active region and between the first portion and the second active region.

In one or more embodiments, the memory device further includes a dielectric layer covering the gate structure and the second active region and disposed between adjacent two of the contacts.

Another aspect of the present invention is to provide a memory device including a substrate, a first active region, a second active region, a gate structure, and a contact. The first active region and the second active region disposed in the substrate. The gate structure is disposed in the substrate and between the first active region and the second active region. The gate structure, the first active region, and the second active region form a memory cell. The contact is disposed on and attached to the first active region. An interface between the contact and the first active region is curved upward along a first direction and curved downward along a second direction substantially orthogonal to the first direction.

In one or more embodiments, the first active region is disposed between and attached to adjacent two of the gate structures along the first direction.

In one or more embodiments, the memory device further includes a first isolation structure disposed between and attached to adjacent two of the first active regions along the second direction.

In one or more embodiments, a top surface of the first isolation structure is lower than the interface, such that the first active regions form a fin-shaped structure.

In one or more embodiments, the memory device further includes a gate dielectric disposed between the gate structure and the first active region and between the gate structure and the second active region.

In one or more embodiments, the memory device further includes an interlayer dielectric disposed on or above the second active region.

In one or more embodiments, the memory cell includes one of the first active region, two of the gate structures, and two of the second active regions. The first active region is disposed between the gate structures, and each of the gate structures is disposed between the first active region and one of the second active regions.

In one or more embodiments, the memory device further includes a plurality of second isolation structures. The memory cell is disposed between adjacent two of the second isolation structures.

In one or more embodiments, the gate structure includes a first portion and a second portion disposed between the first portion and the first active region and between the first portion and the second active region.

In one or more embodiments, the memory device further includes a dielectric layer covering the gate structure and the second active region and disposed between adjacent two of the contacts.

### BRIEF DESCRIPTION OF THE DRAWINGS

FIG. 1 is a schematic diagram of a memory cell according to one embodiment of the present invention;

FIG. 2 is a schematic diagram of a first active layer of FIG. 1;

FIG. 3 is a cross-sectional view taking along line 3-3 of FIG. 1; and

FIG. 4 is a cross-sectional view taking along line 4-4 of FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

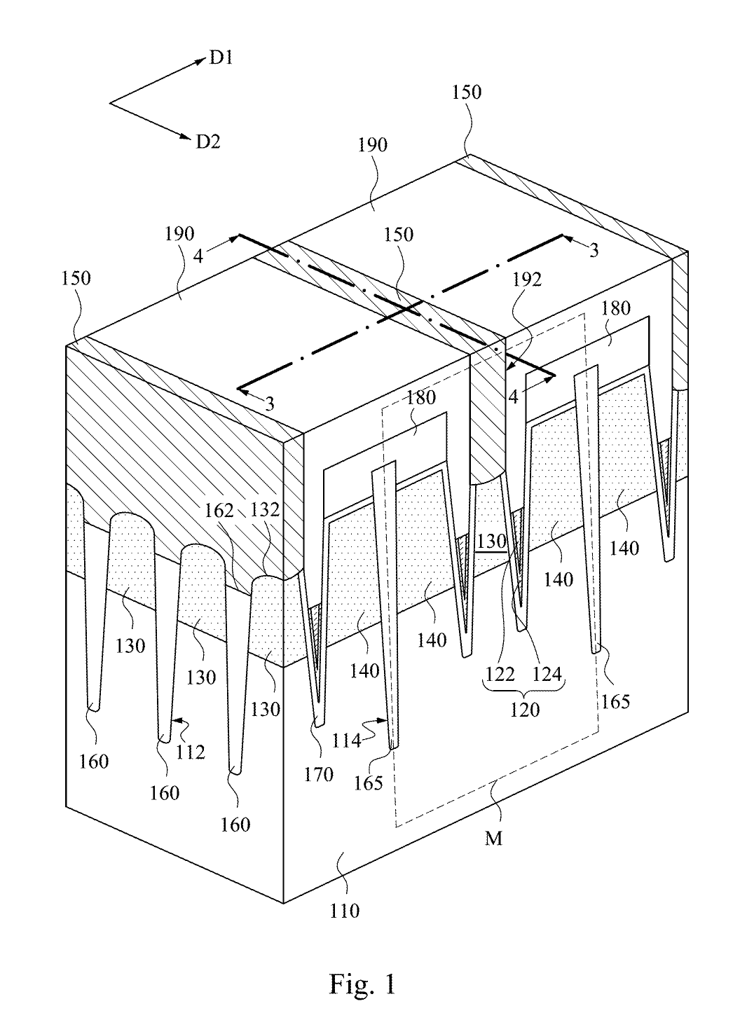

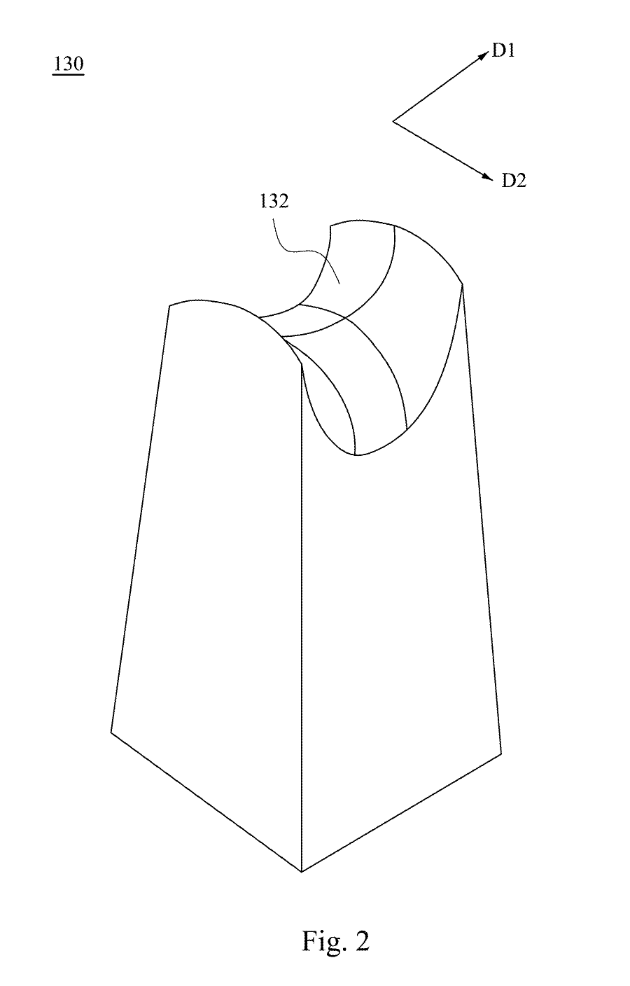

FIG. 1 is a schematic diagram of a memory cell according to one embodiment of the present invention, and FIG. 2 is a schematic diagram of a first active layer 130 of FIG. 1. As shown in FIGS. 1 and 2, the memory device includes a substrate 110, a gate structure 120, a first active region 130, a second active region 140, and a contact 150. The gate structure 120 is disposed in the substrate 110. The first active region 130 and the second active region 140 are disposed in the substrate 110 and are respectively disposed at opposite sides of the gate structure 120. In other words, the gate structure 120 is disposed between the first active region 130 and the second active region 140. The gate structure 120, the first active region 130, and the second active region 140 form a memory cell M. The contact 150 is disposed on and attached to the first active region 130. An interface 132 of the contact 150 and the first active region 130 is saddle-shaped. More specifically, the interface 132 between the contact 150 and the first active region 130 is curved upward along a first direction D1 and curved downward along a second direction D2 substantially orthogonal to the first direction D1.

In this embodiment, the saddle-shaped interface 132 is able to reduce the junction contact resistance between the contact 150 and the first active region 130. In greater detail, the contact 150 is electrically connected to the first active region 130, such that the contact 150 can be an electrically connection between the first active region 130 and an external circuit or element, such as a digit line. In general, the first active region 130 and the contact 150 are made of different materials, a junction contact resistance naturally exists therebetween. One way to reduce the junction contact resistance is to increase the contact area between the first active region 130 and the contact 150 (i.e., the area of the interface 132). In this embodiment, since the interface 132 is a curved interface, more specifically, a saddle-shaped interface, the area thereof is larger than the contact area in a conventional memory device, which is a flat interface. Hence, the junction contact resistance between the first active region 130 and the contact 150 can be efficiently reduced.

In this embodiment, the substrate 110 can be a semiconductor substrate, such as a silicon substrate. The first active region 130 and the second active region 140 can be doped regions in the substrate 100, and respectively function as a source and a drain of the memory cell M, or vice versa. The first active region 130 and the second active region 140 can be n-doped or p-doped, depending on real requirements. Since the gate structure 120 is disposed in the substrate 110, the memory device in this embodiment can be called as a recess access device (RAD). When a bias is applied to the gate structure 120, a channel can be formed in the substrate 110 and around the gate structure 120. Current can flow between the first active region 130 and the second active region 140 through the channel.

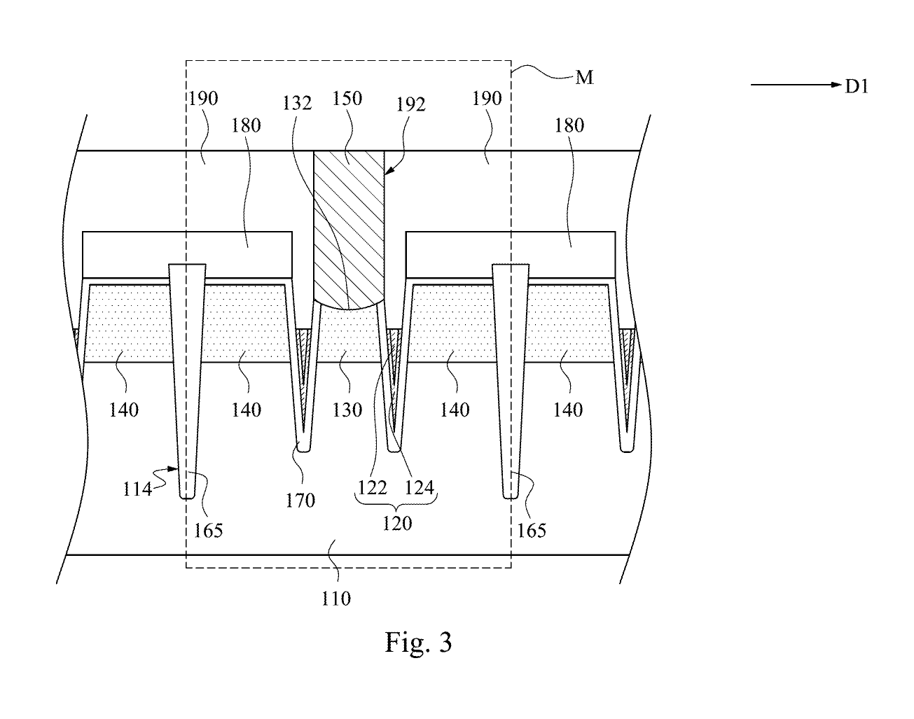

FIG. 3 is a cross-sectional view taking along line 3-3 of FIG. 1. Reference is made to FIGS. 2 and 3. In this embodiment, the first active region 130 is disposed between and attached to adjacent two of the gate structures 120 along the first direction D1, and the interface 132 is curved upward toward the two gate structures 120. That is, the minimum point of the interface 132 along the first direction D1 is substantially located at the center of the adjacent two gate structures 120.

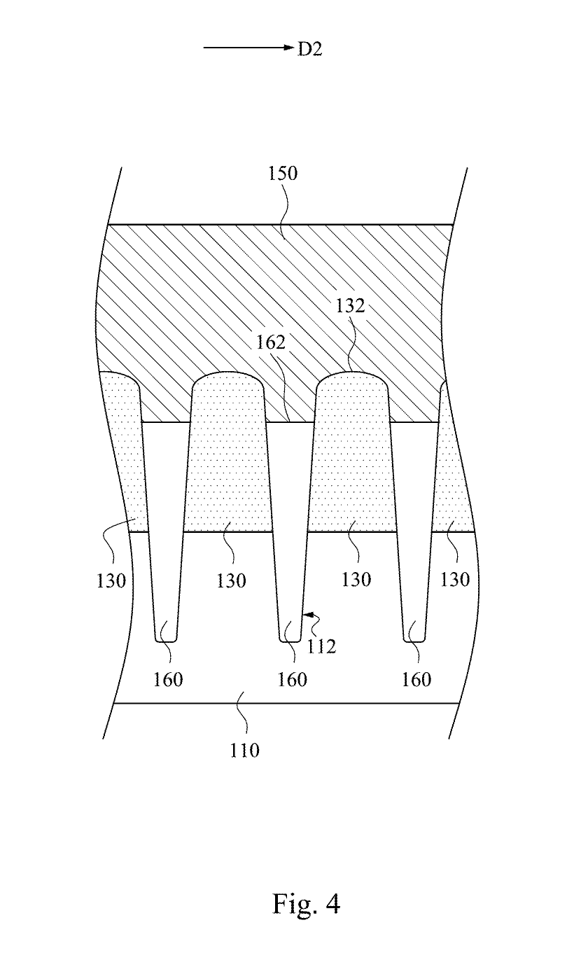

FIG. 4 is a cross-sectional view taking along line 4-4 of FIG. 1. Reference is made to FIGS. 2 and 4. In this embodiment, the memory device further includes a first isolation structure 160 disposed between and attached to adjacent two of the first active regions 130 along the second direction D2. The interface 132 is curved downward toward the first isolation structure 160. In other words, a number of the first isolation structure 160 is plural, and the first active regions 130 and the first isolation structures 160 are alternately arranged along the second direction D2. Therefore, adjacent two of the first active regions 130 are electrically isolated from each other by the first isolation structures 160 disposed therebetween. The maximum point of the interface 132 along the second direction D2 is substantially located at the center of adjacent two of the first isolation structures 160.

In this embodiment, the first isolation structure 160 can be a shallow trench isolation (STI) structure. More specifically, the substrate 110 has a plurality of first trenches 112, and the first isolation structures 160 are respectively filled in the first trenches 112. In some embodiments, the first isolation structure 160 can be made of dielectric materials, such as silicon oxide or other suitable materials.

In this embodiment, a top surface 162 of the first isolation structure 160 is lower than the interface 132, such that the first active regions 130 form a fin-shaped structure, as shown in FIG. 4. The contact 150 further covers the first isolation structure 160. Hence, the top surface 162 of the first isolation structure 160 is an interface between the first isolation structure 160 and the contact 150. Since the top surface 162 is lower than the interface 132, at least portions of sidewalls of the first active regions 130 are exposed by the first isolation structures 160 and attached to the contact 150. Therefore, the contact area between the contact 150 and the first active regions 130 can be increased due to the fin-shaped structure of the first active regions 130.

Reference is made to FIGS. 1 and 3. In this embodiment, the memory device further includes a gate dielectric 170 disposed between the gate structure 120 and the first active region 130 and between the gate structure 120 and the second active region 140. More specifically, the gate dielectric 170 is configured to isolate the gate structure 120, preventing the current of the gate dielectric 170 from leaking to the first active layer 130, the second active layer 140, and/or the substrate 110. The gate dielectric 170 covers the first active region 130 and the second active region 140, and the gate structure 120 is formed on the gate dielectric 170. In some embodiments, the gate dielectric 170 may be made of oxide, such as silicon dioxide, and the claimed scope of the present invention is not limited in this respect.

In this embodiment, the memory device further includes a plurality of second isolation structures 165. The memory cell M is disposed between adjacent two of the second isolation structures 165. More specifically, adjacent two of the first isolation structures 160 and adjacent two of the second isolation structures 165 together define the memory cell M. In this embodiment, the memory cell M includes one of the first active regions 130, two of the gate structures 120, and two of the second active regions 140. The first active region 130 is disposed between the gate structures 120, and each of the gate structures 120 is disposed between the first active region 130 and one of the second active regions 140. Furthermore, each of the second active regions 140 is disposed between one of the gate structures 120 and one of the second isolation structures 165. The first active region 130, one of the second active regions 140, and one of the gate structures 120 form a transistor. Therefore, the memory cell M includes two of the transistors, and the two transistors share the first active region 130.

In this embodiment, the second isolation structure 165 can be a shallow trench isolation (STI) structure. More specifically, the substrate 110 has a plurality of second trenches 114, and the second isolation structures 165 are respectively filled in the second trenches 114. In some embodiments, the second isolation structure 165 can be made of dielectric materials, such as silicon oxide or other suitable materials.

In this embodiment, the memory device further includes an interlayer dielectric (ILD) 180 disposed on or above the second active region 140. Furthermore, the gate dielectric 170 is disposed between the interlayer dielectric 180 and the second active region 140. More specifically, the interlayer dielectric 180 is disposed above and covers two of the second active regions 140 and one of the second isolation structures 165 disposed between the two second active regions 140.

In this embodiment, the gate structure 120 can be a single-layer or multi-layer structure. For example, the gate structure 120 in FIGS. 1 and 3 includes a first portion 122 and a second portion 124 disposed between the first portion 122 and the first active region 130 and between the first portion 122 and the second active region 140. In some embodiments, the first portion 122 is made of tungsten (W), and the second portion 124 is made of titanium nitride (TiN). The second portion 124 can spatially isolate the first portion 122 from the substrate 110. In some other embodiments, the gate structure 120 can be made of tantalum nitride (TaN), tungsten nitride (WN), ruthenium (Ru), molybdenum nitride (MoN), TaN/TiN, WN/TiN, arsenic (As) doped polysilicon, tantalum (Ta), aluminum (Al), titanium (Ti), and zirconium nitride (ZrN), or any combination thereof.

In this embodiment, the memory device further includes a dielectric layer 190 covering the gate structures 120, the second active regions 140, the interlayer dielectric 180, and disposed between adjacent two of the contacts 150. More specifically, the dielectric layer 190 is configured to isolate the contacts 150 and protect the gate structures 120 and the second active regions 140. In some embodiments, an initial dielectric layer (not shown) can be formed above the substrate 110 and covers all of the structures disposed thereon (i.e., the gate structures 120, the first active regions 130, the second active regions 140, and the interlayer dielectric 180). A plurality of grooves 192 are then formed in the initial dielectric layer to respectively expose the first active regions 130. The grooves 192 can be formed using an etching process, for example. During the etching process, the silicon etching rate can be increased to form the saddle-shaped interface 132 if the substrate 110 is a silicon substrate. More specifically, since the silicon etching rate is increased, the first trenches 112 are etched faster than the sidewalls of the first active regions 130. Hence, the interface 132 is curved downward along the second direction D2. Furthermore, since the plasma (for etching) is denser at the center than at the sidewalls of the grooves 192, the center portions of the grooves 192 have higher etching rate than the sidewall portions of the grooves 192, such that the interfaces 132 of the etched first active regions 130 are curved upward along the first direction D1.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

1. A memory device comprising:
a substrate;
at least one gate structure disposed in the substrate;
at least one first active region and at least one second active region disposed in the substrate and respectively disposed at opposite sides of the gate structure, wherein the gate structure, the first active region, and the second active region form a memory cell; and
at least one contact disposed on and attached to the first active region, wherein an interface between the contact and the first active region is saddle-shaped.

2. The memory device of claim 1, wherein the first active region is disposed between and attached to adjacent two of the gate structures, and the interface is curved upward toward the two gate structures.

3. The memory device of claim 1, further comprising:
a first isolation structure disposed between and attached to adjacent two of the first active regions, wherein the interface is curved downward toward the first isolation structure.

4. The memory device of claim 3, wherein a top surface of the first isolation structure is lower than the interface, such that the first active regions form a fin-shaped structure.

5. The memory device of claim 1, further comprising:
a gate dielectric disposed between the gate structure and the first active region and between the gate structure and the second active region.

6. The memory device of claim 1, further comprising:
an interlayer dielectric disposed on or above the second active region.

7. The memory device of claim 1, wherein the memory cell comprises one of the first active region, two of the gate structures, and two of the second active regions, the first active region is disposed between the gate structures, and each of the gate structures is disposed between the first active region and one of the second active regions.

8. The memory device of claim 7, further comprising:
a plurality of second isolation structures, wherein the memory cell is disposed between adjacent two of the second isolation structures.

9. The memory device of claim 1, wherein the gate structure comprises:
a first portion; and
a second portion disposed between the first portion and the first active region and between the first portion and the second active region.

10. The memory device of claim 1, further comprising:
a dielectric layer covering the gate structure and the second active region and disposed between adjacent two of the contacts.

11. A memory device comprising:
a substrate;
at least one first active region and at least one second active region disposed in the substrate;
at least one gate structure disposed in the substrate and between the first active region and the second active region, wherein the gate structure, the first active region, and the second active region form a memory cell; and
at least one contact disposed on and attached to the first active region, wherein an interface between the contact and the first active region is curved upward along a first direction and curved downward along a second direction substantially orthogonal to the first direction.

12. The memory device of claim 11, wherein the first active region is disposed between and attached to adjacent two of the gate structures along the first direction.

13. The memory device of claim 11, further comprising:
a first isolation structure disposed between and attached to adjacent two of the first active regions along the second direction.

14. The memory device of claim 13, wherein a top surface of the first isolation structure is lower than the interface, such that the first active regions form a fin-shaped structure.

15. The memory device of claim 11, further comprising:
a gate dielectric disposed between the gate structure and the first active region and between the gate structure and the second active region.

16. The memory device of claim 11, further comprising:
an interlayer dielectric disposed on or above the second active region.

17. The memory device of claim 11, wherein the memory cell comprises one of the first active region, two of the gate structures, and two of the second active regions, the first active region is disposed between the gate structures, and each of the gate structures is disposed between the first active region and one of the second active regions.

18. The memory device of claim 17, further comprising:
a plurality of second isolation structures, wherein the memory cell is disposed between adjacent two of the second isolation structures.

19. The memory device of claim 11, wherein the gate structure comprises:
a first portion; and
a second portion disposed between the first portion and the first active region and between the first portion and the second active region.

20. The memory device of claim 11, further comprising:
a dielectric layer covering the gate structure and the second active region and disposed between adjacent two of the contacts.
